(19) United States
(12) Patent Application Publication
(10) Pub. No.: US 2009/0208878 A1
(43) Pub. Date: Aug. 20, 2009

(54) Lithographic System, Lithographic Apparatus and Device Manufacturing Method

(75) Inventors: Erik Roelof LOOPSTRA, Eindhoven (NL); Donis George Flagello, Scottsdale, AZ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: ASML Netherlands B.V., Veldhoven (NL)

(21) Appl. No.: 12/212,163

(22) Filed: Sep. 17, 2008

Related U.S. Application Data
(60) Provisional application No. 60/960,354, filed on Sep. 26, 2007.

(51) Int. Cl. G03B 27/54; G03F 7/20

(52) U.S. Cl. 430/322; 355/67

(57) ABSTRACT

A lithographic system includes two lithographic apparatus. A first lithographic apparatus is configured to project a patterned radiation beam onto a first target portion of a substrate. The second lithographic apparatus includes an interferometric arrangement configured to split the radiation beam and to recombine the split beams so as to produce an interference pattern. A masking arrangement is configured to selectively transmit a portion of the interference pattern and a projection system is configured to project the selectively transmitted portion of the interference pattern onto a second target portion of the substrate.

### CROSS REFERENCE TO RELATED APPLICATIONS

This application claims benefit under 35 U.S.C. §119(e) to U.S. Application No. 60/960,354, filed Sep. 26, 2007, which is incorporated by reference herein in its entirety.

### FIELD

The present invention relates to a lithographic system, a lithographic apparatus forming part of the lithographic system, and a method for manufacturing a device using a lithographic system.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction.

A problem arises where it is desired to print part of a desired pattern on the substrate at the highest possible resolution, when other parts of the desired pattern can be printed at a much lower resolution. This situation arises, for example, in a layer of an IC in which the core of a desired IC pattern comprises dense parallel gate lines while the periphery of that pattern includes much larger structures which contact the gate lines.

A single, high resolution lithographic apparatus can be used to print both the core of the pattern and the periphery of the pattern in a single exposure. The lithographic apparatus comprises an illumination system configured to illuminate the patterning device with a beam of radiation. Within a typical illumination system, the beam is shaped and controlled such that at a pupil plane of the illumination system the beam has a desired spatial intensity distribution. The spatial intensity distribution at the pupil plane effectively acts as a virtual radiation source to provide illumination radiation at the patterning device level. Various illumination modes (i.e. shapes of the intensity distribution) can be used, such as “conventional illumination” (a top-hat disc-shaped intensity distribution in the pupil) and/or “off-axis illumination” (e.g., annular, dipole, quadrupole or more complex shaped arrangements of the illumination pupil intensity distribution). For printing the periphery including the larger structures conventional illumination would be desired, whereas for printing the dense lines in the core of the pattern a dipole illumination mode would be desired. In view of the incompatibility of these two illumination modes, there is the problem of having to provide an illumination mode which deviates from any of the desired illumination modes.

### SUMMARY

A possibility for the printing of a combination of dense structures surrounded by less dense structures is the use of a high resolution lithographic apparatus to print the core of the pattern, with a low resolution lithographic apparatus being used to print the periphery of the pattern. In particular, a lithographic apparatus including a high numerical aperture (NA) objective arranged to transfer a pattern of a patterning device onto a substrate via imaging at a four times reduction, together with a corresponding high NA illumination system arranged to provide dipole illumination of the patterning device may be used to image the dense line structures while a lithographic apparatus including a four times reduction objective with a lower numerical aperture in combination with a corresponding lower NA illumination system may be used to image the peripheral structure. Such an arrangement has a disadvantage, however, of the use of two costly lithographic apparatus. The high resolution lithographic apparatus may not be suitable for printing the relatively large structures of the periphery in view of an inefficient machine usage.

A possibility for printing dense lines at high resolution is the use of interferometric lithography, that is the use of an apparatus arranged to provide a standing wave pattern produced by an interference of two or more coherent optical beams, to produce the pattern on the substrate.

U.S. Pat. No. 6,233,044 discloses a lithographic apparatus for producing a pattern on a semiconductor wafer in which some of the spatial frequency components are derived by conventional optical lithography and some by interferometric lithographic techniques.

The apparatus comprises a beamsplitter before the mask illumination (i.e., a beamsplitter disposed upstream of the mask) and two optical paths, and a first imaging optical path, traversing a first imaging optical system, that images diffracted beams corresponding to a high-frequency subset of the mask image onto the wafer die. The apparatus further includes a second reference optical path that provides a reference beam at the wafer die or target portion (for providing interference). The reference beam is incident on the substrate off-axis with respect to the first imaging optical path. In order to avoid exposure of adjacent wafer areas, the reference beam is shaped by a second imaging system containing a field stop for delimiting the exposure area. The shaping is accomplished by arranging the field stop and the second imaging system such as to provide imaging at an astigmatic demagnification of the field stop. Such an arrangement suffers a disadvantage however that a field stop arrangement suitable for use with astigmatic magnification is difficult to implement.

It is desirable, for example, to provide a lithographic system incorporating an interferometric lithographic apparatus which may be used to produce the most dense portion of a pattern on a substrate wherein the scanning of the substrate to expose subsequent portions of a pattern on different regions of the substrate is made possible.

According to an aspect of the invention, there is provided a lithographic system comprising a lithographic system comprising:
a first lithographic apparatus configured to project a patterned radiation beam onto a target portion of a substrate; and
a second lithographic apparatus comprising:
   an illumination system configured to condition a radiation beam,
   an interferometric arrangement comprising a beam splitting arrangement configured to split the radiation beam into split beams and a recombination arrangement configured to recombine the split beams so as to produce an interference pattern at a field plane,
   a masking arrangement configured to selectively transmit a portion of the interference pattern,
   a substrate table configured to hold the substrate, and
   a projection system configured to project the selectively transmitted portion of the interference pattern onto a selected area of the target portion of the substrate.

According to an aspect of the invention, there is provided an apparatus comprising:
an illumination system configured to condition a radiation beam;
an interferometric arrangement configured to split the radiation beam and to recombine the split beams so as to produce an interference pattern at a field plane;
a masking arrangement configured to selectively transmit a portion of the interference pattern;
a substrate table configured to hold the substrate; and
a projection system configured to project the selectively transmitted portion of the interference pattern onto a target portion of the substrate.

According to an aspect of the invention, there is provided a device manufacturing method comprising:
using a first lithographic apparatus:
   to condition a radiation beam,
   to impart the radiation beam with a pattern in its cross-section to form a patterned radiation beam, and
   to project the patterned radiation beam onto a first target portion of the substrate; and
using a second lithographic apparatus:
   to condition a radiation beam,
   to split the radiation beam and to recombine the split beams so as to produce an interference pattern at a field plane,
   to selectively transmit a portion of the interference pattern, and
   to project the selectively transmitted portion of the interference pattern onto a second target portion of the substrate.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts an optical lithographic apparatus for use in a lithographic system according to an embodiment of the invention;

FIG. 2 depicts an interferometric lithographic apparatus for use in the lithographic system;

FIG. 3 depicts a masking arrangement incorporated in the field plane of the apparatus of FIG. 2; and

FIG. 4 discloses a process used to produce a patterned substrate using the apparatus as depicted in FIGS. 1 and 2.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

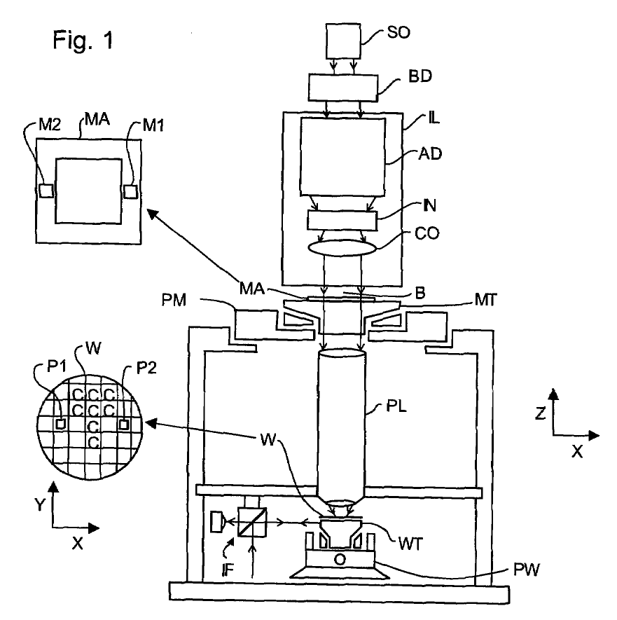

FIG. 1 schematically depicts a lithographic apparatus. The lithographic apparatus includes: an illumination system (illuminator) IL configured to condition a radiation beam B (e.g., DUV or EUV radiation); a support structure (e.g., a mask table) MT configured to support a patterning device (e.g., a mask, a reticle, or a dynamic patterning device) MA and connected to a first positioner PM configured to accurately position the patterning device MA; and a substrate table (e.g., a wafer table) WT configured to hold a substrate (e.g., a resist coated wafer) W and connected to a second positioner PW configured to accurately position the substrate W. The lithographic apparatus also has a projection system PL configured to project a pattern imparted to the radiation beam B by patterning device MA onto a target portion (e.g., comprising one or more dies) C of the substrate W. In the lithographic apparatus the patterning device MA and the projection system PL is transmissive, but alternatively could be reflective.

The illumination system IL may include various types of optical components, such as refractive, reflective, magnetic, electromagnetic, electrostatic or other types of optical components, or any combination thereof, for directing, shaping, or controlling the radiation B.

The support structure MT holds the patterning device MA in a manner that depends on the orientation of the patterning device MA, the design of the lithographic apparatus, and other conditions, such as for example whether or not the patterning device MA is held in a vacuum environment. The support structure MT may use mechanical, vacuum, electrostatic or other clamping techniques to hold the patterning device MA. The support structure MT may be a frame or a table, for example, which may be fixed or movable, as required. The support structure MT may ensure that the patterning device is at a desired position, for example with respect to the projection system PL.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C, such as an integrated circuit.

The patterning device MA may be transmissive or reflective. Examples of patterning devices MA include reticles, masks, programmable mirror arrays, and programmable LCD panels. Masks are well known in lithography, and include mask types such as binary, alternating phase shift, and attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B which is reflected by the mirror matrix.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

The lithographic apparatus may be of a type having two (dual stage) or more substrate tables (and/or two or more mask tables) WT. In such “multiple stage” machines the additional substrate tables WT may be used in parallel, or preparatory steps may be carried out on one or more tables while one or more other substrate tables WT are being used for exposure.

Illuminator IL receives a radiation beam from a radiation source SO. The source SO and the lithographic apparatus may be separate entities, for example when the source SO is an excimer laser. In such cases, the source SO is not considered to form part of the lithographic apparatus, and the radiation beam B passes from the source SO to the illuminator IL with the aid of a beam delivery system BD comprising, for example, suitable directing mirrors and/or a beam expander. In other cases, the source SO may be an integral part of the lithographic apparatus—for example when the source SO is a mercury lamp. The source SO and the illuminator IL, together with the beam delivery system BD, if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator may be adjusted. In addition, the illuminator IL may comprise various other components, such as an integrator IN and a condenser CO. The illuminator IL may be used to condition the radiation beam B, to have a desired uniformity and intensity distribution in its cross section.

The radiation beam B is incident on the patterning device (e.g., mask MA), which is held on the support structure (e.g., mask table MT), and is patterned by the patterning device. Having traversed the mask MA, the radiation beam B passes through the projection system PL, which focuses the beam onto a target portion C of the substrate W. With the aid of the second positioner PW and position sensor IF (e.g., an interferometric device, linear encoder or capacitive sensor), the substrate table WT can be moved accurately, e.g., so as to position different target portions C in the path of the radiation beam B. Similarly, the first positioner PM and another position sensor (which is not explicitly depicted) can be used to accurately position the mask MA with respect to the path of the radiation beam B, e.g., after mechanical retrieval from a mask library, or during a scan.

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (known as scribe-lane alignment marks). Similarly, in situations in which more than one die is provided on the mask MA, the mask alignment marks may be located between the dies.

The lithographic apparatus may be used in at least one of the following modes:

1. In step mode, the support structure (e.g., mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (e.g., mask table) MT and the substrate table WT are scanned synchronously while a pattern imparted to the radiation beam B is projected onto a target portion C (i.e., a single dynamic exposure). The velocity and direction of the substrate table WT relative to the support structure (e.g., mask table) MT may be determined by the (de-)magnification and image reversal characteristics of the projection system PL.

3. In another mode, the support structure (e.g., mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes programmable patterning device, such as a programmable mirror array of a type as referred to herein.

Combinations and/or variations on the described modes of use or entirely different modes of use may also be employed.

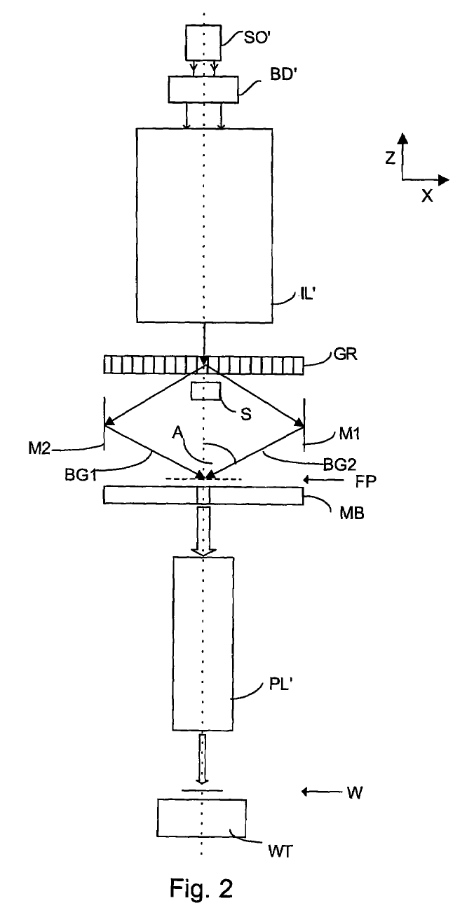

FIG. 2 schematically depicts an interferometric lithographic apparatus for use in the lithographic system according to an embodiment of the invention. In the Figure, features which are generally equivalent to the features of the apparatus shown in FIG. 1 are labeled accordingly. However, the source, SO′, beam delivery system, BD′, and illuminator, IL′, differ from the respective components SO, BD and IL shown in the apparatus of FIG. 1 in that they are arranged to provide a low sigma coherent illumination system. The low sigma coherent illumination system may, for example, include a laser and laser beam shaping optics providing a collimated beam of laser radiation having a value of sigma σ of less than 0.05. Such a system may be made to be considerably cheaper than a conventional variable sigma illumination system.

The lithographic apparatus of FIG. 2 also varies from the apparatus shown in FIG. 1 in that the patterning device, MA, is replaced by an interferometric system comprising a beam splitter in the form of a grating, GR, and a beam recombination system in the form of mirrors M1 and M2, to recombine the beams produced by the grating, GR. The interferometric system is arranged such that the beam produced by the illuminator IL′ produces an interference pattern at a field plane, FP, where the recombined beams BG1 and BG2 interfere, the position of the field plane FP being displaced along the optical axis (shown as a dotted line in FIG. 2) relative to the position of the patterning device MA in the apparatus of FIG. 1. The interference pattern at the plane FP is imaged by the projection system PL′ onto the core of a target portion at the substrate W.

A numerical aperture NA′ of the radiation beams at the field plane FP (in accordance with the angle A in FIG. 2) may have a value in the range of 0.8-0.9. The value of NA′, however, is not limited to this range and can be arranged at any desired value by adjustment of the mirror position and orientation of mirrors M1 and M2, or of only mirror M1 or M2.

A field masking system, in the form of a masking blade system, MB, is provided at or near the field plane, FP. A stop S constructed and arranged to block one or more undesired diffracted orders of radiation emanating from the grating GR, such as residual zeroth order diffracted radiation, is positioned adjacent to the grating GR.

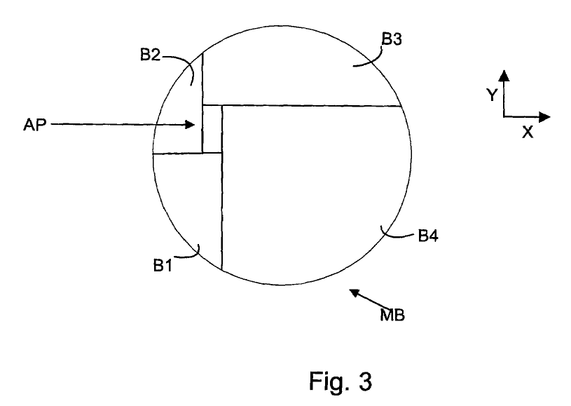

As illustrated in FIG. 3, the masking blade MB may include four blades, B1, B2, B3, B4, which are each movable in the XY plane so as to define between them an aperture AP. During exposure of a target portion, a controller arranged to move the blades B1 and B3 along the Y-direction, moves the blades B1 and B3 such as to open and close the aperture AP synchronously with the scanning stage to delimit an exposed area along the Y-direction. The aperture AP, as shaped by the masking blade system MB, is imaged onto the target portion to delimit the core area of the target portion where the interference pattern is printed. Only a portion of the interference pattern produced at the field plane, FP, is transmitted to the projection system, PL′. The projection system, PL′, is arranged to have a two times demagnification so as to provide imaging at substrate level at a numerical aperture NA″ which may have a value in the range of 1.6-1.8 (in accordance with the range of NA′ mentioned above). The projection system PL′ can be embodied as an immersion projection system for use with immersion liquid, disposed between the projection system and an exposed target portion on the substrate and having a refractive index in the range of 1.5 to 2.0. It will be appreciated that due to the demagnification DM of minus two times, DM=−2, produced by the projection system, PL′, to open and close the aperture AP produced in the masking blade system, MB, the blades B1 and B3 should be moved at twice the velocity of the scanning speed of the substrate table WT. Since the interferometric apparatus will usually be used only to print the relatively small core area of the target portion of a substrate W, such as an area of 5 mm×5 mm there will be time to accelerate the blades B1 and B3 in the masking blade system, MB, to the desired speed. A system for enabling the synchronization of the movement across the interference pattern at the field plane with the scanning movement of the substrate is described, for example, in U.S. Pat. No. 6,882,477.

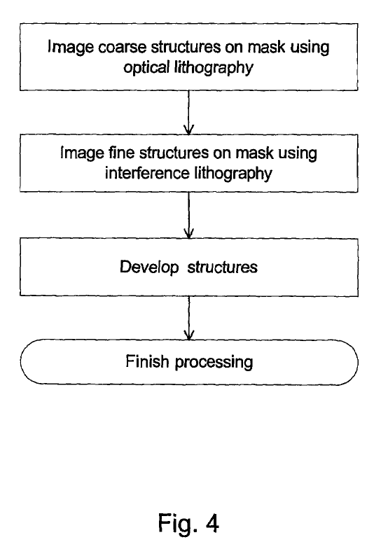

Turning now to FIG. 4, it will be seen that by combination of the use of the conventional lithographic apparatus of FIG. 1, and the interferometric apparatus of FIG. 2, it is possible to print, for example, a complete IC layer pattern on a target portion on the substrate W. For example, a lithographic apparatus of FIG. 1 may be used to expose the periphery of each target portion on the substrate with the corresponding pattern. Next the exposed substrate is transferred by a substrate handling system to the interferometric lithographic apparatus as illustrated in FIG. 2. Subsequently, the core of each target portion on the substrate is exposed to the corresponding pattern of the core (alternatively, the core could be exposed first and the periphery exposed second). Next, the substrate is transported by a substrate handling system to a substrate track apparatus for post exposure processing and resist development.

It will be appreciated that in the particular example shown and described, the demagnification of the projection system, PL, is chosen to be minus two times. However, the demagnification of the projection system PL′ can take any suitable value in accordance with the maximum obtainable numerical aperture NA′ at the field plane FP and the selected numerical aperture NA″ at substrate level.

It will be appreciated that while it is convenient for the beam splitter to comprise a grating GR, there are other possibilities for beam splitters such as a dichroic surface. Furthermore, the recombination mechanism M1, M2 to recombine the split beams may take other forms, for example a prism arrangement instead of or in addition to a mirror.

It will also be appreciated that while the optical lithographic apparatus and the interferometric lithographic apparatus have been described as entirely separate apparatus, it may be possible to combine the two apparatus with appropriate portions of the combined apparatus being adjustable to provide the required functionality.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion,” respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein.

### Conclusion

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A lithographic system comprising:
a first lithographic apparatus configured to project a patterned radiation beam onto a target portion of a substrate; and
a second lithographic apparatus comprising:
an illumination system configured to condition a radiation beam,
an interferometric arrangement comprising a beam splitting arrangement configured to split the radiation beam into split beams and a recombination arrangement configured to recombine the split beams so as to produce an interference pattern at a field plane,
a masking arrangement configured to selectively transmit a portion of the interference pattern,
a substrate table configured to hold the substrate, and
a projection system configured to project the selectively transmitted portion of the interference pattern onto a selected area of the target portion of the substrate.

2. The lithographic system of claim 1, wherein the substrate table is configured to move in correspondence with movement of the transmitted portions of the interference pattern over the field plane.

3. The lithographic system of claim 1, wherein the recombination arrangement is configured to recombine the split beams at a numerical aperture selected from the range of 0.7 to 0.95.

4. The lithographic system of claim 1, wherein the projection system is configured to project the selectively transmitted portion of the interference pattern onto a selected area of the target portion of the substrate at a numerical aperture selected from the range of 1.4 to 1.8.

5. The lithographic system of claim 1, wherein the projection system has a demagnification of minus 2.

6. The lithographic system of claim 1, wherein the illumination system is configured to produce a beam having a value of σ of not greater than 0.05.

7. An apparatus comprising:
an illumination system configured to condition a radiation beam;
an interferometric arrangement configured to split the radiation beam and to recombine the split beams so as to produce an interference pattern at a field plane;
a masking arrangement configured to selectively transmit a portion of the interference pattern;
a substrate table configured to hold the substrate; and
a projection system configured to project the selectively transmitted portion of the interference pattern onto a target portion of the substrate.

8. The apparatus of claim 7, wherein the substrate table is configured to move in correspondence with movement of the transmitted portions of the interference pattern over the field plane.

9. An apparatus of claim 7, wherein the recombination arrangement is configured to recombine the split beams at a numerical aperture selected from the range of 0.7 to 0.95.

10. An apparatus of claim 7, wherein the projection system is configured to project the selectively transmitted portion of the interference pattern onto a selected area of the target portion of the substrate at a numerical aperture selected from the range of 1.4 to 1.8.

11. An apparatus of claim 7, wherein the projection system has a demagnification of minus two.

12. An apparatus of claim 7, wherein the illumination system is configured to produce a beam having a value of σ of not greater than 0.05.

13. A device manufacturing method comprising:
using a first lithographic apparatus:
to condition a radiation beam,
to impart the radiation beam with a pattern in its cross-section to form a patterned radiation beam, and
to project the patterned radiation beam onto a first target portion of a substrate; and
using a second lithographic apparatus:
to condition a radiation beam,
to split the radiation beam and to recombine the split beams so as to produce an interference pattern at a field plane,
to selectively transmit a portion of the interference pattern, and
to project the selectively transmitted portion of the interference pattern onto a second target portion of the substrate.

14. A device manufactured using the system according to claim 1.
